(19) United States
(12) Patent Application Publication
(10) Pub. No.: US 2021/0180178 A1
(43) Pub. Date: Jun. 17, 2021

(54) EVAPORATION SOURCE AND DEPOSITION APPARATUS INCLUDING THE SAME

(71) Applicant: Samsung Display Co., Ltd., Yongin-Si (KR)

(72) Inventor: Jingul KIM, Seoul (KR)

(21) Appl. No.: 16/914,560

(22) Filed: Jun. 29, 2020

(30) Foreign Application Priority Data
Dec. 16, 2019 (KR) 10-2019-0168256

(51) Int. Cl. C23C 14/24; C23C 14/54

(52) U.S. Cl. CPC C23C 14/243; C23C 14/548

(57) ABSTRACT

An evaporation source and a deposition apparatus may include a storage including a crucible and a partition dividing a space formed by the crucible into a plurality of internal spaces, a level control portion disposed in each of the plurality of internal spaces and dividing the each of the plurality of internal spaces into a plurality of sub-spaces having a lattice structure in a plan view, a nozzle portion which is disposed on the storage and is used to eject the deposition source material, a housing in which the storage and the nozzle portion are disposed, and a heating portion which is disposed between the storage and the housing and is used to heat the crucible.

### CROSS-REFERENCE TO RELATED APPLICATIONS

This U.S. non-provisional patent application claims priority under 35 U.S.C. § 119 to Korean Patent Application No. 10-2019-0168256, filed on Dec. 16, 2019, in the Korean Intellectual Property Office, the entire contents of which are hereby incorporated by reference.

### BACKGROUND

The present disclosure relates to an evaporation source and a deposition apparatus including the same, and in particular to an evaporation source, which includes a level control portion suppressing fluctuation of a deposition source material, and a deposition apparatus including the same.

A physical vapor deposition (PVD) method (e.g., a vacuum evaporation method, an ion plating method, or a sputtering method) or a chemical vapor deposition (CVD) method using a gas reaction is used to form a thin film on a substrate.

A deposition apparatus, which is used to perform the vacuum deposition, has an evaporation source which includes a storage containing a deposition source material, a heating portion heating the storage, and a nozzle portion ejecting the deposition source material.

One of the evaporation sources is a linear-type evaporation source that extends in a specific direction. The linear-type evaporation source can be used to effectively form a deposition layer on a substrate of a large area.

### SUMMARY

An embodiment of the inventive concept provides an evaporation source, which allows a deposition process to be performed at a constant deposition rate throughout the deposition process, and a deposition apparatus including the same.

According to an embodiment of the inventive concept, an evaporation source may include a storage, a level control portion, a nozzle portion, a housing, and a heating portion.

In an embodiment, the storage may be a storing structure and may include a crucible, which is used to contain a deposition source material, and a partition, which divides a space formed by the crucible into a plurality of internal spaces. In an embodiment, the deposition source material may be an organic material.

In an embodiment, the crucible may include a rectangular bottom portion whose long sides extends in a first direction and whose short sides extends in a second direction orthogonal to the first direction, and a sidewall portion which extends from the bottom portion in a third direction crossing both of the first direction and the second direction.

In an embodiment, the partition may be provided to cross the long side of the crucible. A height of the sidewall portion in the third direction may be greater than a height of the partition in the third direction.

In an embodiment, the level control portion may divide each of the isolated spaces, which are the internal space of the crucible defined by the partition, into a plurality of sub-spaces.

In an embodiment, the level control portion may have a lattice structure in a plan view. The level control portion may be disposed in the isolated spaces, respectively, which are the internal space of the crucible defined by the partition, and may be permanently affixed to the storage or detachably inserted into the plurality of internal spaces respectively.

In an embodiment, a height of the level control portion in the third direction may be equal to or smaller than the height of the partition.

In an embodiment, the level control portion may be formed of or include titanium (Ti).

In an embodiment, the level control portion may include a first plate and a second plate which serve as a plurality of separating walls. The first plate may have a flat surface that is parallel to a plane formed by the first direction and the third direction. The second plate may be provided to cross the first plate and may have a flat surface that is parallel to a plane formed by the second direction and the third direction.

In an embodiment, a plurality of the second plates may be provided to cross the first plate and may be spaced apart from each other in the second direction.

In an embodiment, the first plate may include a first opening which is formed at at least one edge of the first plate and allows the deposition source material to communicate therethrough. The second plate may include a second opening which is formed at at least one edge of the second plate and allows the deposition source material to communicate therethrough.

In an embodiment, the storage may further include a fastening portion which is provided on the bottom portion of the crucible and is combined to the first opening or the second opening to fasten the level control portion.

In an embodiment, the nozzle portion may be placed on the storage and is used to eject the deposition source material. The nozzle portion may include a nozzle plate having a flat surface which is substantially parallel to the bottom portion of the crucible, and at least one nozzle protruding from the nozzle plate.

In an embodiment, the evaporation source may further include a radiant heat blocking plate having a hole in which the nozzle is inserted, and covering the nozzle plate.

In an embodiment, the storage and the nozzle portion may be contained in the housing.

In an embodiment, the heating portion may be disposed between the storage and the housing and may be used to heat the crucible.

In an embodiment, a deposition apparatus may include a chamber, the evaporation source which is disposed in the chamber and is configured to eject the deposition source material, and an evaporation source transfer which is disposed in the chamber and is used to transfer the evaporation source.

In an embodiment, the chamber may include a first chamber and a second chamber disposed adjacent to each other.

In an embodiment, the evaporation source may be configured to provide the deposition source material to the first chamber and the second chamber in an alternating manner. The evaporation source may include a plurality of evaporation sources which are arranged to be parallel to each other.

In an embodiment, the evaporation source transfer may be used to transfer the evaporation source from one of the first chamber and the second chamber to the other.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view schematically illustrating a structure of a deposition apparatus according to an embodiment of the inventive concept.

FIG. 2 is a sectional view illustrating a schematic structure of a deposition apparatus according to an embodiment of the inventive concept, taken along a moving path of an evaporation source.

FIG. 3 is an exploded perspective view illustrating an evaporation source according to an embodiment of the inventive concept.

FIG. 4 is a perspective view illustrating an evaporation source according to an embodiment of the inventive concept.

FIG. 5 is a sectional view taken along a line I-I′ of FIG. 3.

FIG. 6 is a perspective view illustrating a level control portion according to an embodiment of the inventive concept.

FIGS. 7 and 8 are perspective views, each of which illustrates a level control portion according to an embodiment of the inventive concept.

FIG. 9 is a perspective view illustrating a portion of an evaporation source according to an embodiment of the inventive concept.

FIG. 10 is a sectional view illustrating a portion of an evaporation source according to an embodiment of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown.

Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

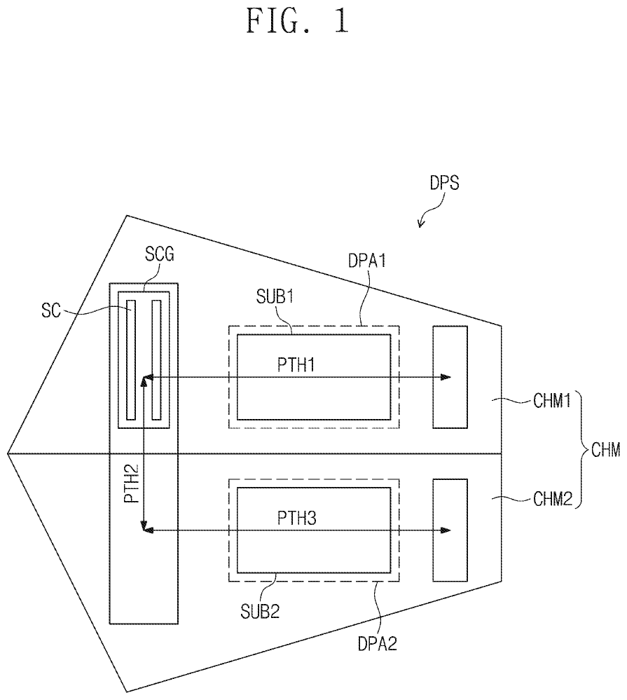

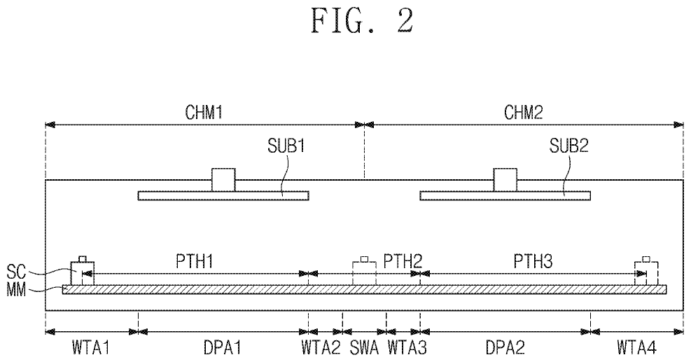

FIG. 1 is a plan view schematically illustrating a structure of a deposition apparatus according to an embodiment of the inventive concept, and FIG. 2 is a sectional view illustrating a schematic structure of a deposition apparatus according to an embodiment of the inventive concept, taken along a moving path of an evaporation source.

Referring to FIGS. 1 and 2, a deposition apparatus DPS according to an embodiment of the inventive concept may include a chamber CHM, in which a substrate is placed, an evaporation source SC, which is provided in the chamber CHM, and a evaporation source transfer MM, which is provided in the chamber CHM and is used to transfer the evaporation source SC.

The chamber CHM may provide a space for a deposition process which is performed on the substrate.

The deposition apparatus DPS may be configured to have only one chamber CHM, but in an embodiment, it may include a plurality of chambers CHM, as shown in FIG. 1. The following description will refer to an example, in which the chamber CHM includes a first chamber CHM1 and a second chamber CHM2 provided adjacent to each other.

The first chamber CHM1 may provide a space for a deposition process which is performed on a first substrate SUB1 and the second chamber CHM2 may provide a space for a deposition process which is performed on a second substrate SUB2.

A vacuum pump (not shown) may be connected to each of the first and second chambers CHM1 and CHM2. The vacuum pump may be used to vacuumize an internal space of each of the first and second chambers CHM1 and CHM2.

Each of the first and second chambers CHM1 and CHM2 may include a deposition region in which the deposition process is substantially performed and a deposition waiting region which is provided at a side of the deposition region.

The first chamber CHM1 may include a first deposition region DPA1, in which the deposition process on the first substrate SUB1 is performed, and a first deposition waiting region WTA1 and a second deposition waiting region WTA2 which are provided at opposite sides of the first deposition region DPA1 with the first deposition region DPA1 interposed between the first deposition waiting region WTA1 and the second deposition waiting region WTA2.

The second chamber CHM2 may include a second deposition region DPA2 in which the deposition process on the second substrate SUB2 is performed and a third deposition waiting region WTA3 and a fourth deposition waiting region WTA4 which are provided at opposite sides of the second deposition region DPA2.

The first and second chambers CHM1 and CHM2 may further include a swing region SWA which is disposed between the second deposition waiting region WTA2 of the first chamber CHM1 and the third deposition waiting region WTA3 of the second chamber CHM2. The first and second chambers CHM1 and CHM2 may share the swing region SWA.

The evaporation source SC may provide a deposition source material to the substrate. In an embodiment, the deposition source material may be an organic material.

One evaporation source SC may be used for a deposition, but in an embodiment, a plurality of evaporation sources SC may be used for the deposition to constitute an evaporation source group SCG, as shown in FIG. 1. In the case where various deposition source materials are deposited on the substrate, two or more evaporation sources SC may be provided in the deposition apparatus DPS. In such a case, the evaporation sources SC may be arranged to be parallel to each other. The evaporation source SC will be described in more detail below.

The evaporation source transfer MM may be used to move the evaporation source SC in each of the first and second chambers CHM1 and CHM2. In addition, the evaporation source transfer MM may be used to transfer the evaporation source SC from the first chamber CHM1 to the second chamber CHM2 or vice versa.

In an embodiment, the evaporation source SC may be configured to provide the deposition source material to the first and second chambers CHM1 and CHM2 in an alternating manner.

The evaporation source SC in the first chamber CHM1 may reciprocate between the first deposition waiting region WTA1 and the second deposition waiting region WTA2 through the first deposition region DPA1. The evaporation source SC may move along a first path PTH1 which passes through the first deposition waiting region WTA1, the first deposition region DPA1, and the second deposition waiting region WTA2. When the deposition process on the first substrate SUB1 is not performed, the evaporation source SC may be placed in the first deposition waiting region WTA1 or the second deposition waiting region WTA2. When the deposition process on the first substrate SUB1 is performed, the evaporation source SC may provide the deposition source material to the first substrate SUB1 while reciprocating between opposite ends of the first substrate SUB1 several times along the first path PTH1 in the first deposition region DPA1.

When the deposition process in the first chamber CHM1 is finished, the evaporation source SC may be transferred to the second chamber CHM2. The evaporation source SC may move from the second deposition waiting region WTA2 of the first chamber CHM1 to the third deposition waiting region WTA3 of the second chamber CHM2 through the swing region SWA. The evaporation source SC may move along a second path PTH2 which passes through the second deposition waiting region WTA2 of the first chamber CHM1, the swing region SWA, and the third deposition waiting region WTA3 of the second chamber CHM2. The second path PTH2 is illustrated to be linear, but the inventive concept is not limited to this example. For example, in an embodiment, the second path PTH2 may be set to form a curved line (e.g., an arc shape).

The evaporation source SC, which is moved to the second chamber CHM2, may reciprocate between the third deposition waiting region WTA3 and the fourth deposition waiting region WTA4 of the second chamber CHM2 through the second deposition region DPA2. The evaporation source SC may move along a third path PTH3, which passes through the third deposition waiting region WTA3, the second deposition region DPA2, and the fourth deposition waiting region WTA4.

Similar to that in the first chamber CHM1, when the deposition process on the second substrate SUB2 is not performed, the evaporation source SC may be placed in the third deposition waiting region WTA3 or the fourth deposition waiting region WTA4, and when the deposition process on the second substrate SUB2 is performed, the evaporation source SC may provide the deposition source material to the second substrate SUB2 while reciprocating between opposite ends of the second substrate SUB2 several times along the third path PTH3 in the second deposition region DPA2.

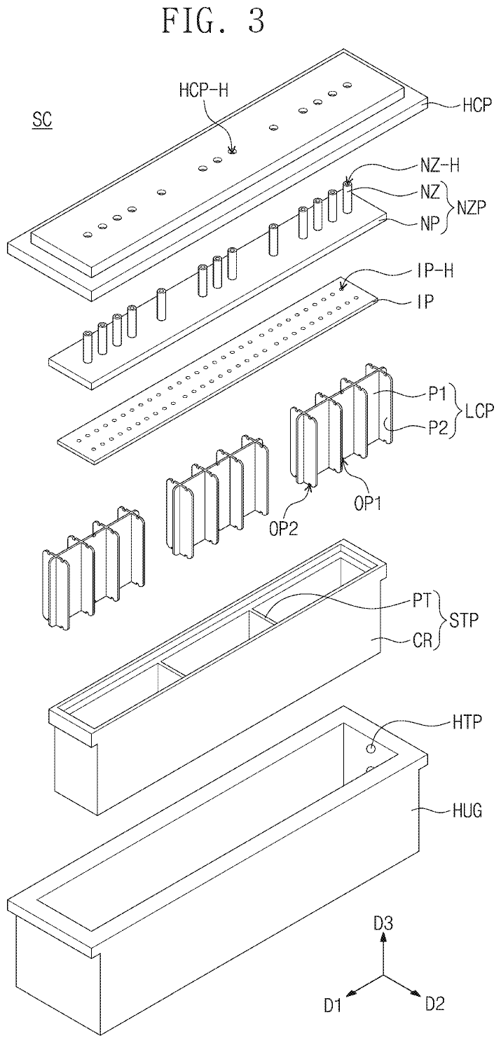

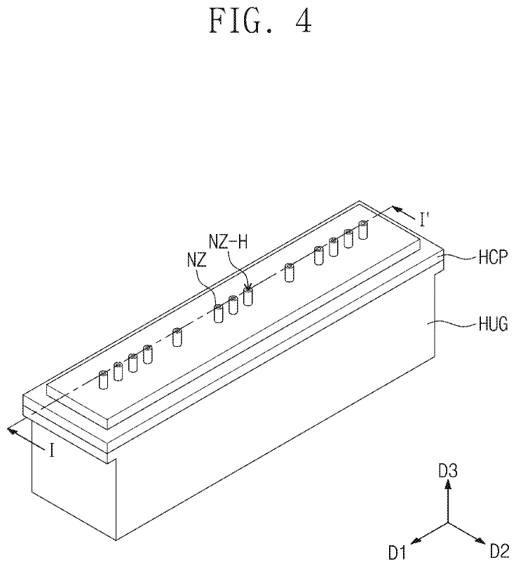

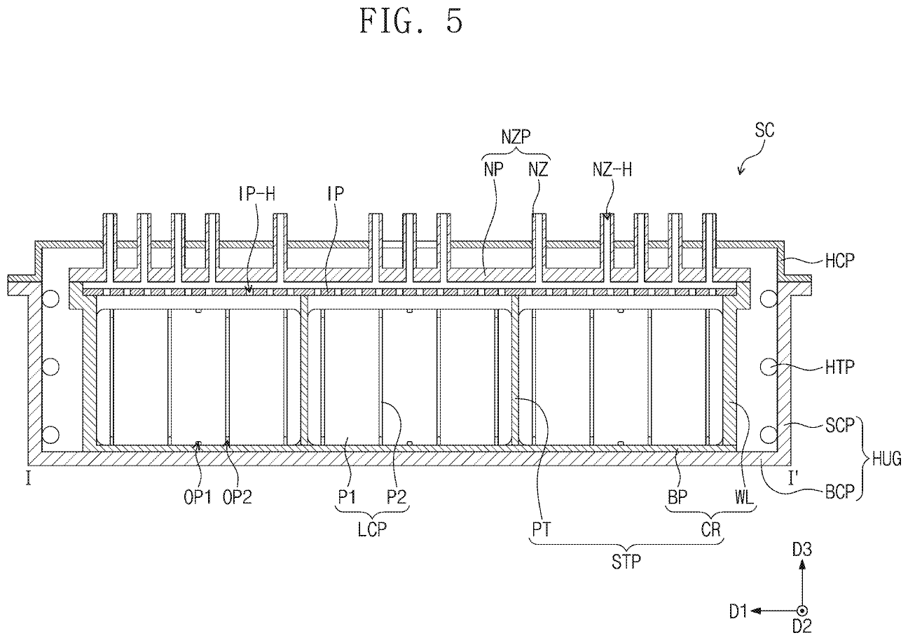

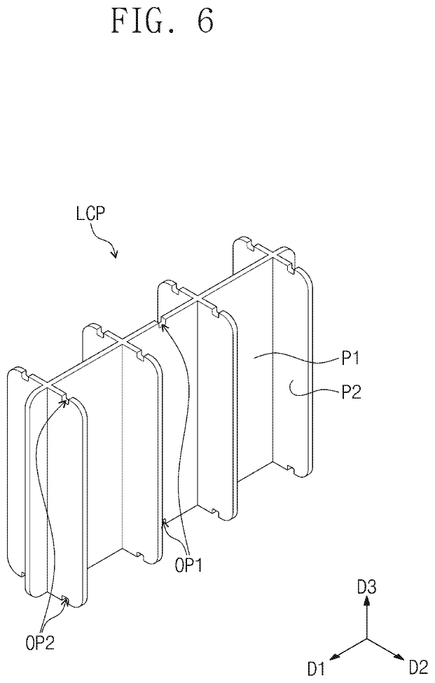

FIG. 3 is an exploded perspective view illustrating an evaporation source according to an embodiment of the inventive concept. FIG. 4 is a perspective view illustrating an evaporation source according to an embodiment of the inventive concept, and FIG. 5 is a sectional view taken along a line I-I′ of FIG. 3. FIG. 6 is a perspective view illustrating a level control portion according to an embodiment of the inventive concept. Hereinafter, the evaporation source SC will be described in more detail.

Referring to FIGS. 3 to 5, the evaporation source SC may include a storage STP, a level control portion LCP, a nozzle portion NZP, an inner plate IP, a radiant heat blocking plate HCP, a heating portion HTP, and a housing HUG.

The storage STP may be used to store the deposition source material and may include a crucible CR and a partition PT sectioning an internal space of the crucible CR.

In an embodiment, the crucible CR may be a rectangular parallelepiped structure, whose long sides are parallel to a first direction D1, whose short sides are parallel to a second direction D2 that is orthogonal to the first direction D1, and whose height is measured in a third direction D3 that is orthogonal to both of the first and second directions D1 and D2.

The crucible CR may include a bottom portion BP which is provided to have a rectangular shape and a sidewall portion WL which extends from the bottom portion BP in a direction perpendicular to the bottom portion BP to determine the height of the crucible CR.

In an embodiment, the partition PT may be a plate-shape structure which has a flat surface parallel to a plane formed by the second and third directions D2 and D3 and is provided to cross the long side of the crucible CR.

A length of the partition PT in the third direction D3 (hereinafter, a height of the partition PT) may be shorter than a length of the sidewall portion WL in the third direction D3 (hereinafter, a height of the sidewall portion WL).

In an embodiment, at least one partition PT may be provided to divide the internal space of the crucible CR into a plurality of internal spaces. The partition PT may separate the deposition source material, which is contained in the crucible CR, into a plurality of portions and may prevent the deposition source material from being distributed ununiformly in the crucible CR.

Although not shown, the partition PT may include a passage, through which the deposition source material can communicate each other. Due to the passage in the partition PT, it may be possible to maintain an amount of the deposition source material contained in each of the internal spaces of the crucible CR that are divided by the partition PT.

The partition PT and the crucible CR may be provided to form a single structure, for example, the partition PT may be permanently affixed to the crucible CR. In an embodiment, the crucible CR and the partition PT may be formed of or include the same material, for example, titanium (Ti).

The level control portion LCP may divide the internal spaces of the crucible CR, which are divided by the partition PT, into a plurality of smaller internal spaces (sub-spaces). The level control portion LCP may divide the deposition source material, which is contained in the crucible CR, into a plurality of smaller portions and may prevent the deposition source material from being distributed ununiformly in the crucible CR.

The level control portion LCP may be inserted into each of the internal spaces of the crucible CR, which are divided by the partition PT, and may be affixed to or separated from the storage STP. In the case where the level control portion LCP is separated from the storage STP, the level control portion LCP and the storage STP may be easily cleaned.

The level control portion LCP may be formed of or include the same material as that of the crucible CR and the partition PT. For example, the level control portion LCP may be formed of or include titanium (Ti).

Referring to FIGS. 5 and 6, the level control portion LCP may have a lattice structure in a plan view. The level control portion LCP may include separating walls, which are disposed in each of the isolated spaces of the crucible CR divided by the partition PT to divide each of the internal spaces into a plurality of sub-spaces.

The level control portion LCP may include a first plate P1 and a second plate P2 which are provided across each other and thereby serve as the separating walls. The following description will refer to an example, in which the first plate P1 and the second plate P2 are disposed to be perpendicular to each other, but the inventive concept is not limited to this example.

In an embodiment, the first plate P1 may be a plate-shaped structure, which has a flat surface parallel to a plane formed by the first and third directions D1 and D3. A length of the first plate P1 in the third direction D3 (i.e., a height of the first plate P1) may be smaller than the height of the sidewall portion WL. In addition, the height of the first plate P1 may be substantially the same as or smaller than the height of the partition PT. A length of the first plate P1 in the first direction D1 may be substantially the same as or smaller than a width of the internal space of the crucible CR which is defined by the partition PT in the first direction D1.

The second plate P2 may be a plate-shaped structure which has a flat surface parallel to a plane formed by the second and third directions D2 and D3. A length of the second plate P2 in the third direction D3 (i.e., a height of the second plate P2) may be substantially the same as the height of the first plate P1. However, the inventive concept is not limited to this example, and the height of the first plate P1 and the height of the second plate P2 may be different from each other. A length of the second plate P2 in the second direction D2 may be substantially the same as a width of the internal space of the crucible CR defined by the partition PT in the second direction D2.

As shown in FIG. 3, the level control portion LCP may be configured to include a plurality of second plates P2. In the case where the plurality of the second plates P2 are provided, the second plates P2 may be spaced apart from each other by a constant distance.

Each of the first and second plates P1 and P2 may include an opening, though which the deposition source material can communicate each other.

The first plate P1 may have a first opening OP1 which is formed at at least one edge portion thereof and allows the deposition source material to communicate in the second direction D2. The first opening OP1 may be formed in a lower edge portion of the first plate P1 adjacent to the bottom portion BP of the crucible CR. In certain embodiments, the first opening OP1 may be formed in an upper edge portion of the first plate P1 that is opposite to the lower edge portion of the first plate P1. The first opening OP1 may be formed in the upper edge portion and the lower edge portion of the first plate P1.

The second plate P2 may have a second opening OP2, which is formed at at least one edge thereof and allows the deposition source material to communicate in the first direction D1. The second opening OP2 may be formed in a lower edge portion of the second plate P2 adjacent to the bottom portion BP of the crucible CR. In certain embodiments, the second opening OP2 may be formed in an upper edge portion of the second plate P2 that is opposite to the lower edge portion of the second plate P2. The second opening OP2 may be formed in the upper edge portion and the lower edge portion of the second plate P2.

In the case where the first and second openings OP1 and OP2 are respectively provided in the upper edge portions of the first and second plates P1 and P2, the level control portion LCP may be inserted into the internal space of the crucible CR divided by the partition PT without any restriction in its insertion direction.

In an embodiment, each of the first and second openings OP1 and OP2 may be spaced apart from an intersection point of the first and second plates P1 and P2 by a specific distance.

The nozzle portion NZP may be provided on the storage STP and may be used to eject the deposition source material. The nozzle portion NZP may include a nozzle plate NP and at least one nozzle NZ which protrudes from the nozzle plate NP.

The nozzle plate NP may have a flat surface, which is substantially parallel to the bottom portion BP of the crucible CR, and may be stably placed on the sidewall portion WL of the storage STP.

In an embodiment, the nozzle portion NZP may be configured to include a plurality of nozzles NZ which are spaced apart from each other in the first direction D1 by the constant distance or in a specific manner. In an embodiment, the nozzles NZ which are arranged in the first direction D1 may be disposed to have at least two different distances, as shown in FIGS. 3 and 4. The distance between the nozzles NZ may be variously changed depending on the kind of the evaporation material, the size of the storage STP, or the size of the deposition target (i.e., the substrate).

The nozzle NZ may have a nozzle hole NZ-H which is formed to penetrate the nozzle NZ and the nozzle plate NP, and an evaporation material in the storage STP may be ejected to the outside of the evaporation source SC through the nozzle NZ and may be deposited on the substrate.

The inner plate IP may be placed between the storage STP and the nozzle portion NZP and may have a plurality of dispersion holes IP-H. The inner plate IP may be used as a filter. In addition, the inner plate IP may be configured to uniformly provide the evaporation material, which is evaporated from the storage STP, to the nozzle NZ.

The inner plate IP may be disposed on a supporting portion, which is defined by the sidewall portion WL of the crucible CR. However, the inventive concept is not limited to this example, and in an embodiment, the storage STP may further include an additional support (not shown), on which the inner plate IP can be disposed.

The radiant heat blocking plate HCP may be disposed on the nozzle portion NZP. The radiant heat blocking plate HCP may have a hole HCP-H, in which the nozzle NZ is inserted, and may cover the nozzle plate NP. The radiant heat blocking plate HCP may be disposed on the housing HUG.

The radiant heat blocking plate HCP may prevent or suppress heat, which is emitted from the heating portion HTP, from being supplied into the chamber CHM. Accordingly, it may be possible to prevent heat, which is emitted from the heating portion HTP and the storage STP, from affecting the deposition process or causing the damage of the chamber CHM.

The radiant heat blocking plate HCP may be formed of or include a material whose heat transfer rate and heat dissipation rate are relatively low. For example, the radiant heat blocking plate HCP may be formed of or include at least one of manganese (Mn), titanium (Ti), ZrO₂, Al₂O₃, TiO₂, boron nitride (PBN), aluminum nitride (ALN), or steel use stainless (SUS).

The heating portion HTP may be configured to heat the storage STP and to evaporate the deposition source material in the storage STP. The heating portion HTP may be placed at the outside of the sidewall portion WL of the crucible CR. However, the inventive concept is not limited to this example, and in an embodiment, the heating portion HTP may be placed to enclose the sidewall portion WL and/or the bottom portion BP of the crucible CR.

In an embodiment, a plurality of the heating portions HTP may be provided. In such a case, temperatures of the heating portions HTP may be controlled in the simultaneous or independent manner.

The housing HUG may be used to contain the storage STP, the nozzle portion NZP, and the heating portion HTP. In an embodiment, the housing HUG may include a bottom cover portion BCP, which is parallel to a plane formed by the first direction D1 and the second direction D2, and a side cover portion SCP, which extends from the bottom cover portion BCP in a direction perpendicular to the bottom cover portion BCP (e.g., the third direction D3). In an embodiment, the radiant heat blocking plate HCP may be placed on and fastened to the side cover portion SCP. The heating portion HTP may be affixed to an inner side surface of the side cover portion SCP.

According to an embodiment of the inventive concept, since the evaporation source SC and the deposition apparatus DPS include the level control portion LCP, it may be possible to suppress fluctuation of the deposition source material, which may occur when the evaporation source SC is transferred.

According to the conventional technology, in the case where a deposition process is immediately performed after moving the evaporation source SC from the first chamber CHM1 to the second chamber CHM2 or from the second chamber CHM2 to the first chamber CHM1, the deposition process may be performed by using the deposition source material which is distributed ununiformly in the internal space of the crucible CR, at its starting point. This may cause a difference in deposition rate (Å/s) between start and end points of the deposition process.

However, according to an embodiment of the inventive concept, the level control portion LCP may be used to prevent the fluctuation of the deposition source material, and thus, it may be possible to uniformly maintain the deposition rate (Å/s) in the deposition process throughout the deposition process. As a result, the deposition layer may be uniformly formed on the substrate.

Hereinafter, an evaporation source and a deposition apparatus according to an embodiment of the inventive concept will be described in more detail with reference to the accompanying drawings. In the following description, a previously described element may be identified by the same reference number without repeating an overlapping description thereof, for the sake of brevity.

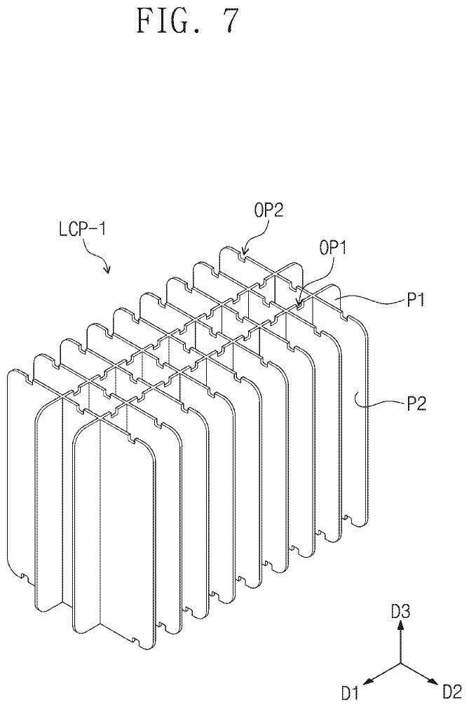

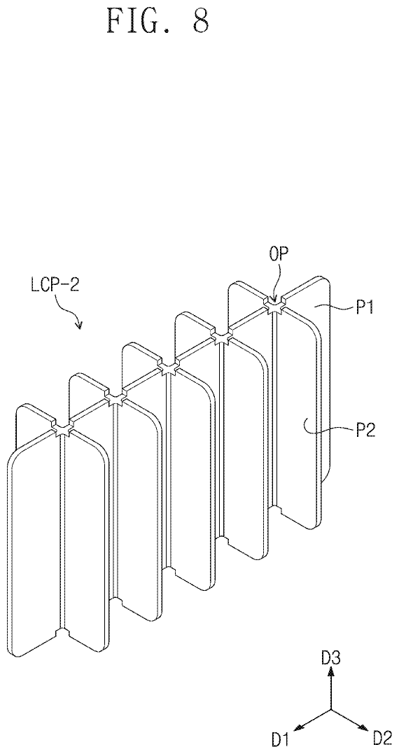

FIGS. 7 and 8 are perspective views, each of which illustrates a level control portion according to an embodiment of the inventive concept.

Referring to FIG. 7, a level control portion LCP-1 according to an embodiment of the inventive concept may include a plurality of the first plates P1 and a plurality of the second plates P2.

The first plates P1 may be spaced apart from each other by a specific distance and may be parallel to each other. Each of the first plates P1 may include the first opening OP1, through which the deposition source material can communicate.

The second plates P2 may be spaced apart from each other by a specific distance and may be parallel to each other. Each of the second plates P2 may be disposed to cross the first plates P1. Each of the second plates P2 may include the second opening OP2, through which the deposition source material can communicate.

Referring to FIG. 8, a level control portion LCP-2 according to an embodiment of the inventive concept may include an opening OP, which is provided at an intersection point of the first and second plates P1 and P2 and allows the deposition source material to communicate therethrough. The opening OP may be formed at an intersection point of the first and second plates P1 and P2 at upper edges and lower edges.

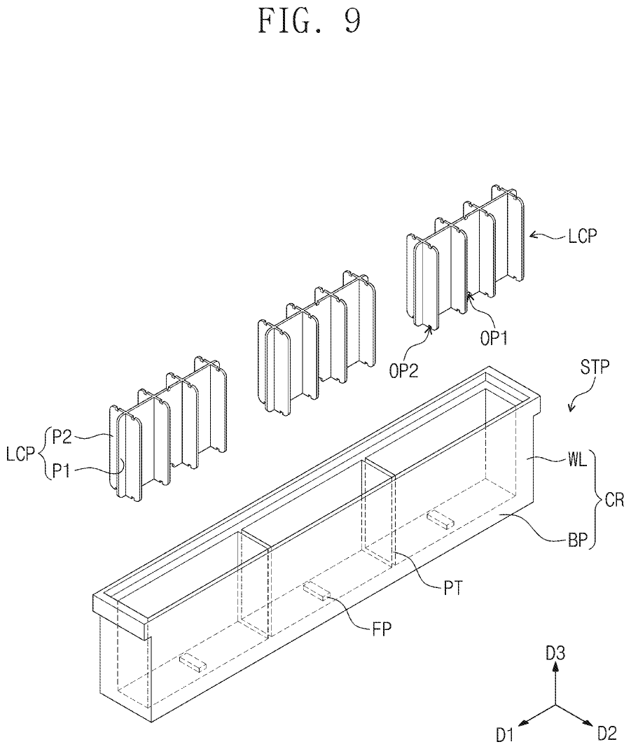

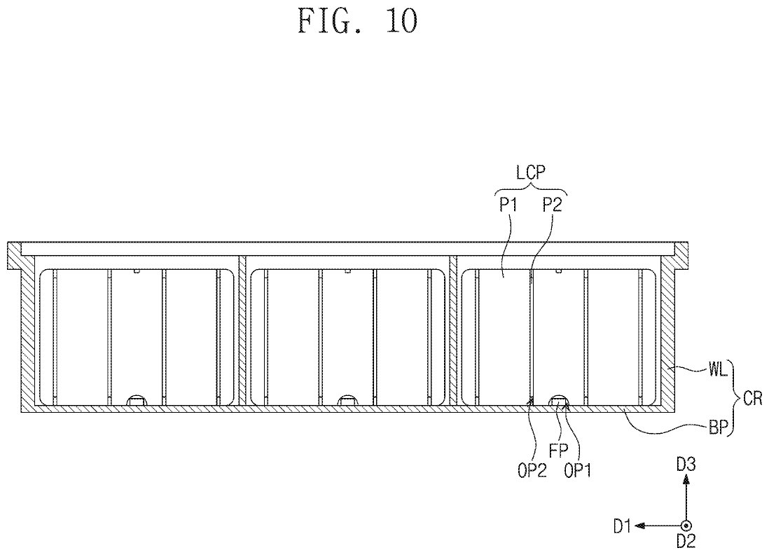

FIG. 9 is a perspective view illustrating a portion of an evaporation source according to an embodiment of the inventive concept, and FIG. 10 is a sectional view illustrating a portion of an evaporation source according to an embodiment of the inventive concept.

Referring to FIGS. 9 and 10, the storage STP may further include a fastening portion FP which is used to fasten the level control portion LCP.

The fastening portion FP may be provided on the bottom portion BP of the crucible CR. The fastening portion FP may protrude from the bottom portion BP of the crucible CR and may be combined to the first or second opening OP1 or OP2 of the level control portion LCP. FIG. 10 illustrates an example, in which the fastening portion FP is combined to the first opening OP1 of the level control portion LCP, but the inventive concept is not limited to this example. For example, the fastening portion FP may be provided at a position corresponding to the second opening OP2 and may be combined to the second opening OP2. In an embodiment, a plurality of the fastening portions FP may be provided, and in this case, the fastening portions FP may be combined to the first and second openings OP1 and OP2, respectively. At least a portion of the first and second opening OP1 or OP2 of the level control portion LCP may have a size greater than the fastening portion to have an extra portion through which the deposition source material can communicate.

In the case where the level control portion LCP is fastened to the fastening portion FP, the level control portion LCP may be prevented from being moved within the internal space of the crucible CR defined by the partition PT.

In an embodiment, it may be possible to use the level control portion LCP fastened to the storage STP, even when the length of the first plate P1 in the first direction D1 is smaller than the width, in the first direction D1, of the internal space of the crucible CR defined by the partition PT or the length of the second plate P2 in the second direction D2 is smaller than the width, in the second direction D2, of the internal space of the crucible CR defined by the partition PT.

According to an embodiment of the inventive concept, an evaporation source and a deposition apparatus including the same may be configured to suppress fluctuation of a deposition source material, which may occur when an evaporation source is transferred in a process chamber, and this makes it possible to uniformly form a deposition layer throughout the entire deposition process.

While example embodiments of the inventive concepts have been particularly shown and described, it will be understood by one of ordinary skill in the art that variations in form and detail may be made therein without departing from the spirit and scope of the attached claims.

What is claimed is:

1. An evaporation source, comprising:
a storage comprising a crucible which is used to contain a deposition source material and a partition dividing a space formed by the crucible into a plurality of internal spaces;
a level control portion disposed in each of the plurality of internal spaces and dividing the each of the plurality of internal spaces into a plurality of sub-spaces having a lattice structure in a plan view;
a nozzle portion which is disposed on the storage and is used to eject the deposition source material;
a housing in which the storage and the nozzle portion are disposed; and
a heating portion which is disposed between the storage and the housing and is used to heat the crucible.

2. The evaporation source of claim 1, wherein the level control portion is permanently affixed to the storage or detachably inserted into the plurality of internal spaces, respectively.

3. The evaporation source of claim 2, wherein the crucible comprises a rectangular bottom portion whose long sides extends in a first direction and whose short sides extends in a second direction orthogonal to the first direction, and a sidewall portion which extends from the bottom portion in a third direction crossing both of the first direction and the second direction, and
wherein the partition is provided to cross the long side of the crucible.

4. The evaporation source of claim 3, wherein a height of the sidewall portion extending in the third direction is greater than a height of the partition extending in the third direction.

5. The evaporation source of claim 4, wherein a height of the level control portion extending in the third direction is equal to or smaller than the height of the partition.

6. The evaporation source of claim 5, wherein the level control portion comprises:
a first plate having a flat surface parallel to a plane formed by the first direction and the third direction; and
a second plate crossing the first plate and having a flat surface parallel to a plane formed by the second direction and the third direction.

7. The evaporation source of claim 6, wherein the first plate comprises a first opening which is formed at at least one edge portion of the first plate and allows the deposition source material to communicate therethrough, and the second plate comprises a second opening which is formed at at least one edge portion of the second plate and allows the deposition source material to communicate therethrough.

8. The evaporation source of claim 7, wherein the storage further comprises a fastening portion which is provided on the bottom portion of the crucible and is combined to the first opening or the second opening to fasten the level control portion.

9. The evaporation source of claim 3, wherein the nozzle portion comprises:
a nozzle plate having a flat surface which is substantially parallel to the bottom portion of the crucible; and
at least one nozzle protruding from the nozzle plate.

10. The evaporation source of claim 9, further comprising a radiant heat blocking plate having a hole in which the nozzle is inserted and covering the nozzle plate.

11. The evaporation source of claim 1, wherein the deposition source material is an organic material.

12. The evaporation source of claim 1, wherein the level control portion comprises titanium (Ti).

13. A deposition apparatus, comprising:
a chamber;
an evaporation source which is disposed in the chamber and is used to eject a deposition source material; and
an evaporation source transfer which is disposed in the chamber and is used to transfer the evaporation source,
wherein the evaporation source comprises:
a storage comprising a crucible which is used to contain the deposition source material and a partition which divides a space formed by the crucible into a plurality of internal spaces,
a level control portion disposed in each of the plurality of internal spaces and dividing the each of the plurality of internal spaces into a plurality of sub-spaces having a lattice structure in a plan view,
a nozzle portion which is disposed on the storage and is used to eject the deposition source material,
a housing in which the storage and the nozzle portion are disposed, and
a heating portion which is disposed between the storage and the housing and is used to heat the crucible.

14. The deposition apparatus of claim 13, wherein the chamber comprises a first chamber and a second chamber which are disposed adjacent to each other.

15. The deposition apparatus of claim 14, wherein the evaporation source is configured to provide the deposition source material to the first chamber and the second chamber in an alternating manner.

16. The deposition apparatus of claim 15, wherein the evaporation source transfer is used to transfer the evaporation source from one of the first chamber and the second chamber to the other.

17. The deposition apparatus of claim 13, wherein the evaporation source comprises a plurality of evaporation sources which are arranged to be parallel to each other.

18. The deposition apparatus of claim 13, wherein the level control portion is permanently attached to the storage or detachably inserted into the plurality of internal spaces.

19. The deposition apparatus of claim 13, wherein the deposition source material is an organic material.

20. An evaporation source, comprising:
a storing structure comprising a crucible containing a deposition source material and a partition dividing an internal space of the crucible into a plurality of spaces;
a level control portion comprising a plurality of separating walls which are respectively disposed in the plurality of spaces, each of the plurality of spaces being divided into a plurality of sub-spaces by the plurality of separating walls; and
a nozzle portion which is disposed on the storing structure and is used to eject the deposition source material,
wherein each of the separating walls comprises:
a first plate extending in a first direction; and
a plurality of second plates each of which is disposed to cross the first plate and is spaced apart from each other in a second direction perpendicular to the first direction.
